(19) United States
(12) Patent Application Publication
(10) Pub. No.: US 2011/0294444 A1
(43) Pub. Date: Dec. 1, 2011

(54) SWITCHING DEVICE, RADIO FREQUENCY SIGNAL SWITCH, AND RADIO FREQUENCY SIGNAL AMPLIFICATION MODULE

(75) Inventor: Hiroaki KAWANO, Osaka (JP)

(73) Assignee: PANASONIC CORPORATION, Osaka (JP)

(21) Appl. No.: 13/113,337

(22) Filed: May 23, 2011

(30) Foreign Application Priority Data
May 25, 2010 (JP) 2010-119856

(51) Int. Cl. H04B 1/44; H01L 29/772

(52) U.S. Cl. 455/83; 257/365; 257/E29.242

(57) ABSTRACT

A small switching device capable of implementing low-distortion characteristics formed on a semiconductor substrate to switch radio frequency signal paths is provided. An FET which is an example of switching device formed on a semiconductor substrate 109 includes two source/drain electrodes each of which is comb-shaped, at least two gate electrodes meandering between the two source/drain electrodes, and a conductive layer interposed between adjacent gate electrodes along the adjacent gate electrodes, in which a layer immediately underneath straight-line portions of the gate electrode is electrically separated from a layer immediately underneath angled portions of the gate electrode, each of the straight-line portions being in parallel with each of teeth of said two source/drain electrodes, and each of the angled portions connecting a pair of adjacent straight-line portions.

### BACKGROUND OF THE INVENTION

(1) Field of the Invention

The present invention relates to switching devices which control the transmission and blocking of signals, and more particularly, relates to a switching device which intermittently transmits radio frequency signals, a radio frequency signal switch and a radio frequency signal amplification module using the switching device.

(2) Description of the Related Art

A configuration in which one antenna is used for transmission and reception is widely used in mobile communication devices such as mobile phones. In such a configuration, it is necessary to switch circuits connected to the antenna depending on whether the signals are transmitted or received, and a radio frequency signal switch is used for the switching. Furthermore, not only the connection with the antenna, the radio frequency switch is used when switching the circuits according to the communication scheme and output power.

It is necessary for such a radio frequency signal switch to suppress interruption waves which adversely affect communications and to intermittently transmit high-power radio frequency signals. Thus, it is necessary for the switching device used for the radio frequency signal switch to have good distortion characteristics sufficient to suppress generation of harmonic waves and high power durability for intermittently transmitting high-power radio frequency signals. Furthermore, for reducing power consumption at the time of transmission and for increasing the reception sensitivity at the time of reception, it is necessary to suppress insertion loss to a low level.

Field Effect Transistors (FET) are widely used for the switching device of the radio frequency signal switch. In such a radio frequency signal switch, in order to increase the power durability, a technology using a multi-gate FET which is an FET with more than one gate electrodes between the source electrode and the drain electrode, and a technology for dispersing power applied to each of the FETs by connecting the multi-gate FETs in series in multiple stages have been generally used.

The operations of a general radio frequency signal switch shall be described with reference to the circuit diagram of the radio frequency signal switch 800 illustrated in FIG. 11.

The radio frequency signal switch 800 in FIG. 11 includes a receiving terminal 801, a transmission terminal 802, an antennal terminal 803, an FET unit 804 connected between the reception terminal 801 and the antenna terminal 803, an FET unit 805 connected between the transmission terminal 802 and the antennal terminal 803, an electric potential fixed resistor 806, a gate resistor 807, a radio frequency coupling capacitor 808, a control terminal 809 for the FET unit 804, and a control terminal 810 for the FET unit 805.

Each of the FET units 804 and 805 in the radio frequency signal switch 800 includes multi-gate Heterojunction FETs (HFET) with two gate electrodes frequently used as switching devices connected in two stages in series.

At the time of transmission, ON voltage is applied to the control terminal 810, and OFF voltage is applied to the control terminal 809. As a result, the FET unit 805 conducts, and the FET unit 804 does not conduct. Thus, the radio frequency signal provided from the transmission terminal 802 is transmitted to the antenna terminal 803.

In each FET composing the FET unit 805, the source electrode and the drain electrode conduct. Thus, the electric potential in the semiconductor layer between the two gate electrodes is the same as the source electrode and the drain electrode. Here, the Schottky barrier diode in each FET in the FET unit 805 has a forward bias. Thus, the potential difference between source and gate and between drain and gate is equal to an on-set voltage of the diode, and is almost constant. Therefore, in each FET in the FET unit 805, the electric potential between the source electrode and the gate electrode and between the drain electrode and the gate electrode are stable.

On the other hand, in each FET composing the FET unit 804, source electrode and the drain electrode do not conduct. As a result, direct-current potential in the semiconductor layer between two gate electrodes of FETs in the FET unit 804 is unstable. This instability is not desirable since it degrades power durability and distortion characteristics of the FET which is in nonconductive state.

At the time of reception, ON voltage is applied to the control terminal 809, and OFF voltage is applied to the control terminal 810. As a result, the receiving terminal 801 and the antenna terminal 803 conduct. Since the receiving signal has smaller power than the transmission signal, the power durability of the FET rarely causes problem at the time of reception.

As described above, in the multi-gate FET, the direct current potential of the semiconductor layer becomes unstable between the gate electrodes in a nonconductive state, and the instability is not preferable since it degrades power durability and distortion characteristics of the multi-gate FET. In order to address this problem, a technology for suppressing the degradation in characteristics in the multi-gate FET by providing a conductive layer between the gate electrodes to stabilize the DC potential in the conductive layer has been proposed (for example, see Patent Literature 1: Japanese Patent No. 4272142).

More specifically, Patent Literature 1 discloses a structure in a multi-gate FET having a structure in which two gate electrodes and a conductive layer are arranged in a meandered shape (hereafter referred to as meander structure) between two comb-shaped source/drain electrodes that are arranged opposite to each other. FIG. 12 is a planar view schematically illustrating an FET 900 with the meander structure.

The FET 900 includes two comb-shaped source/drain electrodes 101 arranged opposite to each other to interlock their teeth, two meander-shaped gate electrodes 102 meandering between the two source/drain electrodes 101, a meander-shaped conductive layer 103 formed along the two gate electrodes 102 between the two gate electrodes 102, and a electric potential fixed resistor 106 provided at one end of the conductive layer 103.

The electric potential fixed resistor 106 stabilizes DC potential of the semiconductor region interposed by the two gate electrodes 102 (that is, below the conductive layer 103) when the FET 900 does not conduct. Thus, the FET 900 is unlikely to cause the degradation in characteristics described above.

In addition, comb-shaped source/drain electrodes 101 are provided in the FET 900. This allows a gate width, which is the overall length of the source/drain electrodes 101 to be long for a relatively small footprint. In FET, it is necessary to expand the gate width as the input power increases. The structure with the comb-shaped source/drain electrodes is beneficial for implementing a small FET for large power.

### SUMMARY OF THE INVENTION

However, the inventors of the present invention have noticed the following problems of the FET with the meander structure. Further description shall be made with reference to FIG. 12.

The first problem is that electric field concentration at the angled portions 107 of the gate electrodes 102 reduces the gate breakdown voltage, degrading the power durability. The electric field concentration at the angled portion 107 also degrades ESD breakdown strength.

The second problem is that the shapes of the gate electrodes 102 and the source/drain electrodes 101 are different in the angled portions 107 and the straight-line portions 108; as a result, they have different the electric characteristics as transistors. Such unevenness in the electric characteristics is undesirable since it leads to degradation in distortion characteristics.

However, a solution to the problem in the FETs with meander structure is still unknown.

In response to this problem, it is an object of the present invention to provide a switching device with a meander structure suitable for miniaturization and capable of reducing the degradation of transistor characteristics, a radio-frequency signal switch, and a radio-frequency signal amplification module using the switching device.

In order to solve this problem, an aspect of the switching device according to the present invention is a switching device formed on a semiconductor substrate, the switching device including: two source/drain electrodes each of which is comb-shaped and having teeth, the two source/drain electrodes being arranged opposite to each other to interlock the teeth; at least two gate electrodes which have a meandered shape meandering between the two source/drain electrodes; and a conductive layer interposed between adjacent gate electrodes among the at least two gate electrodes and along the adjacent gate electrodes, in which a layer immediately underneath straight-line portions of the at least two gate electrodes is electrically separated from a layer immediately underneath angled portions of the at least two gate electrodes, each of the straight-line portions being in parallel with each of the teeth of the two source/drain electrodes, and each of the angled portions connecting a pair of adjacent straight-line portions.

Here, the layer immediately underneath the angled portions of the gate electrodes may lose the function of the switching device as a transistor only at the angled portions. For example, a layer immediately underneath the angled portions of the at least two gate electrodes may be a semiconductor layer, and the semiconductor layer is inactivated by ion implantation. The layer may be electrically separated from the layer immediately underneath the straight-line portions by forming trenches at the angled portions. Furthermore, an insulating film may be formed immediately underneath the gate electrode at the angled portions to electrically separate the insulating film from the layer immediately underneath the straight-line portions. With this, it is possible to suppress the reduction in breakdown voltage due to electric field concentration and the degradation of the distortion characteristics due to uneven electric characteristics in the angled portions of the gate electrodes.

Furthermore, the layer immediately underneath the angled portions of the conductive layer and the layer immediately underneath the straight-line portion of the conductive layer may be electrically connected. For example, the conductive layer may be formed by the N-type semiconductor layer formed in the active region.

This allows simplification of the manufacturing method and miniaturization of the device. On the other hand, the layer immediately underneath the angled portion of the gate electrode is electrically separated from the layer immediately underneath the straight-line portion of the gate electrodes. Thus, the effects of the present invention are not inhibited.

Another aspect of the radio-frequency signal switch according to the present invention is a single pole double throw radio-frequency signal switch including an antenna terminal connected to an antenna, a transmission terminal to which a signal for the antenna is applied, a receiving terminal for outputting a signal from the antenna, a first switching device connected between the transmission terminal and the antenna terminal, and a second switching device connected between the receiving terminal and the antenna terminal, in which, the first and second switching devices are configured to be controlled such that (i) at the time of transmission, the first switching device conducts, and the second switching device does not conduct, and (ii) at the time of reception, the first switching terminal conducts, and the second switching device does not conduct, and each of the first and second switching devices is a switching device formed on a semiconductor substrate, the switching device including: two source/drain electrodes each of which is comb-shaped and having teeth, the two source/drain electrodes being arranged opposite to each other to interlock the teeth; at least two gate electrodes which have a meandered shape meandering between the two source/drain electrodes; and a conductive layer interposed between adjacent gate electrodes among the at least two gate electrodes and along the adjacent gate electrodes, in which a layer immediately underneath straight-line portions of the at least two gate electrodes is electrically separated from a layer immediately underneath angled portions of the at least two gate electrodes, each of the straight-line portions being in parallel with each of the teeth of the two source/drain electrodes, and each of the angled portions connecting a pair of adjacent straight-line portions.

With this, it is possible to implement a small radio-frequency signal switch capable of intermittently transmitting high-power radio-frequency signals and with good distortion characteristics.

Furthermore, an aspect of the radio-frequency signal amplification module according to the present invention is a radio-frequency signal amplification module including: a first terminal to which a radio-frequency signal is applied; a second terminal for outputting an amplified radio-frequency signal; a first radio frequency signal switch which is a single pole single throw switch; a second radio frequency signal switch which is a single pole single throw switch; a first amplifier (i) having: an input terminal connected to the first terminal through the first radio frequency signal switch; and an output terminal connected to the second terminal through the second radio frequency switch, and (ii) for amplifying a radio frequency signal applied to the input terminal and outputting the amplified radio-frequency signal to the output terminal; a second amplifier having: an input terminal connected to the first terminal; and an output terminal connected to the second terminal, and for amplifying a radio frequency signal applied to the input terminal and outputting the amplified radio-frequency signal to the output terminal; and a controller for exclusively operating the first and second amplifiers, and for controlling the first and second radio frequency switches such that the first and second radio frequency signal switches conduct when the first amplifier is in operation, and that the first and second radio frequency signal switches does not conduct when the second amplifier is in operation, in which each of the first and second radio frequency signal switches is a switching device formed on a semiconductor substrate, the switching device including: two source/drain electrodes each of which is comb-shaped and having teeth, the two source/drain electrodes being arranged opposite to each other to interlock the teeth; at least two gate electrodes which have a meandered shape meandering between the two source/drain electrodes; and a conductive layer interposed between adjacent gate electrodes among the at least two gate electrodes and along the adjacent gate electrodes, in which a layer immediately underneath straight-line portions of the at least two gate electrodes is electrically separated from a layer immediately underneath angled portions of the at least two gate electrodes, each of the straight-line portions being in parallel with each of the teeth of the two source/drain electrodes, and each of the angled portions connecting a pair of adjacent straight-line portions.

With this, a small radio-frequency signal switch capable of intermittently transmitting high-power radio-frequency signals and with good distortion characteristics is used, which allows implementation of a radio-frequency signal amplification module suitable for application such as mobile communication devices including mobile phones, for example.

As described above, according to the present invention, in the switching device with a meander structure, it is possible to alleviate problems by electrically separating the layer immediately underneath the angled portions and the layer immediately underneath the straight-line portions. The problems include, for example, reduction in the breakdown voltage due to electric field concentration at the angled portions, and the uneven electric characteristics of the transistor in the angled portions and the straight-line portions.

Therefore, it is possible to provide a small switching device with good power durability and distortion characteristics, a radio-frequency signal switch, and a radio-frequency signal amplification module.

### FURTHER INFORMATION ABOUT TECHNICAL BACKGROUND TO THIS APPLICATION

The disclosure of Japanese Patent Application No. 2010-119856 filed on May 25, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a planar view illustrating a switching device according to Example 1 of Embodiment 1 of the present invention;

FIG. 1B is a cross-sectional view of the switching device according to Example 1 (cross-sectional view along A-A′ in FIG. 1A);

FIG. 1C is a cross-sectional view of the switching device according to Example 1 (cross-sectional view along B-B′ in FIG. 1A);

FIG. 2 is a chart illustrating a comparison of P1dBs of the switching devices according to the prior art and Example 1 of the present invention;

FIG. 3 is a chart illustrating a comparison of ESD breakdown voltage of the switching devices according to the prior art and Example 1 of the present invention;

FIG. 4A is a chart illustrating the second harmonic distortions in the switching devices according to the prior art and Example 1 of the present invention;

FIG. 4B is a chart illustrating the third harmonic distortions in the switching devices according to the prior art and Example 1 of the present invention;

FIG. 5A is a planar view illustrating a switching device according to Example 2 of Embodiment 1 of the present invention;

FIG. 5B is a cross-sectional view of the switching device according to Example 2 (cross-sectional view along A-A′ in FIG. 5A);

FIG. 5C is a cross-sectional view of the switching device according to Example 2 (cross-sectional view along B-B′ in FIG. 5A);

FIG. 6A is a planar view illustrating a switching device according to Example 3 of Embodiment 1 of the present invention;

FIG. 6B is a cross-sectional view of the switching device according to Example 3 (cross-sectional view along A-A′ in FIG. 6A);

FIG. 6C is a cross-sectional view of the switching device according to Example 3 (cross-sectional view along B-B′ in FIG. 6A);

FIG. 7A is a planar view illustrating a switching device according to Example 4 of Embodiment 1 of the present invention;

FIG. 7B is a cross-sectional view of the switching device according to Example 4 (cross-sectional view along A-A′ in FIG. 7A);

FIG. 7C is a cross-sectional view of the switching device according to Example 4 (cross-sectional view along B-B′ in FIG. 7A);

FIG. 8 is a circuit diagram of a radio-frequency signal switch according to Embodiment 3 of the present invention;

FIG. 9 is a functional block diagram of a radio-frequency signal amplification module according to Embodiment 4 of the present invention;

FIG. 10A is a planar view of a semiconductor device implementing main components of the radio-frequency signal amplification module according to Embodiment 4; FIG. 10B is a cross-sectional view of the semiconductor device according to Embodiment 4 of the present invention (cross-sectional view along A-A′ in FIG. 10A);

FIG. 10C is a cross-sectional view of the semiconductor device according to Embodiment 4 of the present invention (cross-sectional view along B-B′ in FIG. 10A);

FIG. 11 is a circuit diagram of a general radio-frequency circuit; and

FIG. 12 is a planar view of the switching device according to Prior Art.

### DESCRIPTION OF THE PREFERRED EMBODIMENTS

The following shall describe examples of embodiments for implementing the present invention with reference to the drawings.

First, note that the same reference numerals are assigned in the drawings to components substantially representing the same configuration, operation, and effects. Furthermore, the numbers described in the following are examples for specifically describing the present invention; the present invention is not limited to the exemplified numbers. In addition, although not particularly limiting, the present invention is specifically suitable for a semiconductor device formed on a Silicon On Insulator (SOI) semiconductor substrate and on a compound semiconductor substrate including, for example, Gallium Arsenide. Furthermore, the type of the FET of the present invention is not particularly limited, but some of the most suitable types include HFET and MEtal Semiconductor FET (MESFET).

### Embodiment 1

The switching device according to Embodiment 1 is a multigate FET in which at least two gate electrodes and a conductive layer are arranged in a meandered shape between two comb-shaped source/drain electrodes arranged opposite to each other, and a layer positioned immediately underneath a straight-line portion of the at least two gate electrodes in parallel with the teeth of the two source/drain electrodes is electrically separated with a layer immediately underneath angled portions connecting the adjacent straight-line portions of the at least two gate electrodes.

For example, the layer immediately underneath the straight-line portion is an active region of the semiconductor layer, and the layer immediately underneath the angled portions is the inactive region which is an inactivated semiconductor layer is inactivated. They may be electrically separated. Furthermore, for example, the layer immediately underneath the straight-line portion may be an insulating layer formed above the semiconductor layer.

According to this configuration, the regions under the angled portions of the switching device do not function as transistor. As a result, the problems of adverse effects in the angled portion due to electric field concentration and uneven electric characteristics of transistor are alleviated.

The following illustrates four FETs with such features, and each of the examples specifically illustrates configuration, operations, and effects.

### Example 1

This example illustrates a case in which HFET is used. HFET is particularly suitable for the present invention.

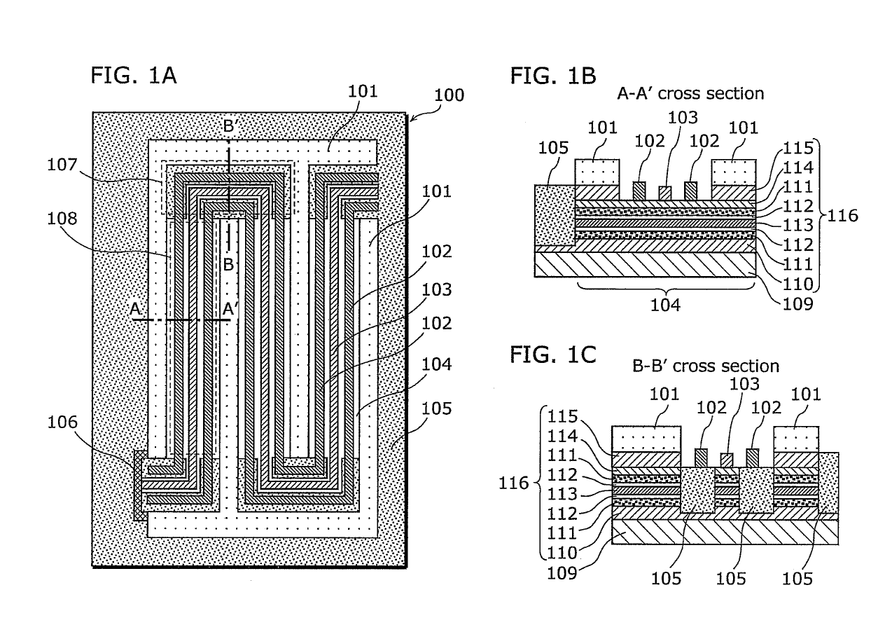

FIG. 1A is a planar view of the FET 100 in this example. FIG. 1B illustrates a cross-sectional view (cross-sectional view along the cross-section A-A′ in FIG. 1A) of the FET 100, and FIG. 1C illustrates a cross-sectional view of the FET 100 (cross-sectional view along the cross section B-B′ in FIG. 1A).

On the semiconductor substrate 109, the epitaxial layer 116 is formed to achieve good crystallinity. The epitaxial layer 116 includes the following layers formed on the semiconductor substrate 109 in this order, for example, a buffer layer 110, an electron supply layer 111, a spacer layer 112, a channel layer 113, another spacer layer 112, another electron supply layer 111, a Schottky barrier layer 114, and a contact layer 115. Note that, the buffer layer 110 is formed to buffer lattice mismatch at a junction of the semiconductor substrate 109 and the epitaxial layer 116. The spacer layer 112 is formed to isolate the electron supply layer 111 and the channel layer 113 for suppressing scattered electrons in the channel layer 113 in which electrons run.

Although this is not particularly limiting, the semiconductor substrate 109 is formed of a GaAs semi-insulating substrate; the buffer layer 110 is formed of GaAs and AIGaAs which are undoped or doped with O (Oxygen); the electron supply layer 111 is formed of n-type doped AlGaAs; the spacer layer 112 is formed of undoped GaAs; the channel layer 113 is formed of undoped InGaAs; the Schottky barrier layer 114 is formed of AlGaAs; and the contact layer 115 is formed of n-type doped GaAs, for example. Si (silicon) and others are used as doping species for n-type doping of AIGaAs and GaAs.

Usually, the contact layer 115 is a high-concentration n-type semiconductor layer, and two source/drain electrodes 101 are formed thereon. In addition, the two gate electrodes 102 are formed in a region between the source/drain electrodes 101. In a region where the gate electrodes 102 are formed, the contact layer 115 is etched to a depth at which the Schottky barrier layer 114 is exposed on the surface of the epitaxial layer 116. Furthermore, in part of the region between the two gate electrodes 102, no etching is performed on the contact layer 115, and the conductive layer 103 is formed with the remaining contact layer 115. Furthermore, crystallinity of the region not related to the operation of the FET 100 such as the space between devices is broken by ion implantation on the epitaxial layer 116 to form a high-resistance inactive region 105.

Although this is not particularly limiting, the width of the teeth of the source/drain electrodes 101 is designed in a minimum width which allows acceptable line resistance, and is approximately 1 to 4 μm, for example. Furthermore, the width of the two gate electrodes 102 is usually designed to be 1 μm or less, and is approximately 0.5 μm, for example. Furthermore, in terms of the miniaturization and insertion loss reduction, it is preferable to maintain the size of the conductive layer 103 as small as possible without causing voltage drop in the conductive layer 103. For example, sheet resistance of the contact layer is usually designed to be approximately 20 to 100 Ω, and the current flowing the conductive layer 103 is small and approximately 1 μA or less. In this case, approximately 0.5 μm is suitable for the width of the conductive layer 103.

Furthermore, it is preferable to set the interval between the gate electrode 102 and the source/drain electrode 101 and the interval between the gate electrode 102 and the conductive layer 103 to the minimum as long as increase in parasitic capacitance and reduction in breakdown voltage do not cause any problem, and are usually designed to be approximately 0.5 to 2 μm. Note that, impurity species such as O (Oxygen), B (Boron), He (Helium) and others are used for ion implantation for forming the inactive region 105.

The FET 100 illustrated in FIG. 1A is an FET with meander structure in which multiple FET units are electrically connected to be in parallel. The FET 100 has a layout including two comb-shaped source/drain electrodes 101 formed opposite to each other to interlock the teeth, two meandered shape gate electrodes 102 between the source/drain electrodes 101, and the meandered shape conductive layer 103 is formed between and along the gate electrodes 102. For stabilizing the electric potential, the conductive layer 103 is connected to the source/drain electrodes 101 through the electric potential fixed resistor 106.

The gate electrode 102 is formed in the active region 104 in the straight-line portions 108 interposed between teeth of the two source/drain electrodes 101, and is formed in the inactive region 105 in the angled portions 107 connecting the adjacent straight-line portions. Here, the inactive region 105 is formed by modifying the active region 104 provided for the operation of the FET 100 as a transistor into a high-resistance region by ion implantation.

The description for the active region 104 and the inactive region 105 in the straight-line portions 108 and the angled portions 107 shall be made with reference to cross-sectional views of the FET 100. As illustrated in FIG. 1B, the FET 100 is formed in the active region 104 in the straight-line portions 108, and one straight-line portion 108 functions as one unit FET. Note that, the inactive region 105 is formed outside the FET 100 for isolating devices. On the other hand, in the angled portion 107, in addition to the device isolation outside the FET 100 as illustrated in FIG. 1C, the inactive region 105 is formed from the Schottky barrier layer 114 immediately underneath the gate electrodes 102 to the semiconductor layer underneath.

As described above, the gate electrode 102 formed in the active region 104 in the angled portion 107 degrades the power durability due to electric field concentration and degrades the distortion characteristics due to uneven transistor characteristics. However, forming the gate electrode 102 on the inactive region 105 prevents such degradations.

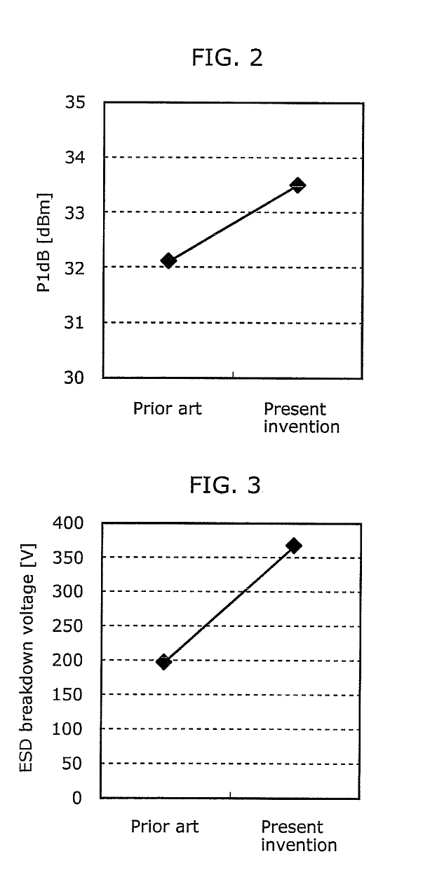

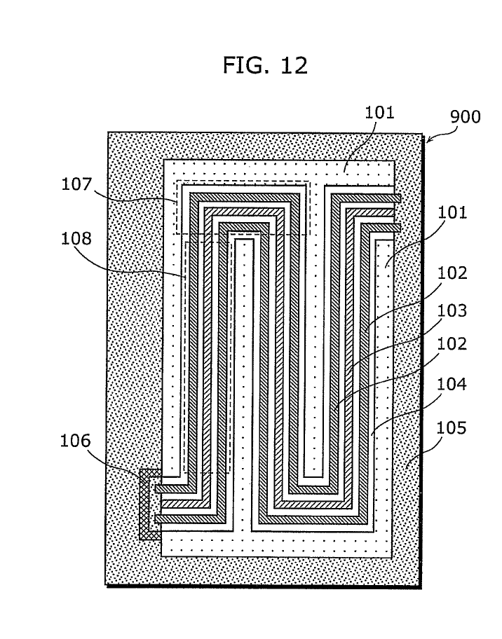

FIG. 2 illustrates output powers at the time of 1 dB gain compression (hereafter referred to as P1dB) of the FET 900 (see FIG. 12) and the FET 100 according to this example. The frequency of input signals is 2 GHz. Applying the present invention increases P1dB, improving the power durability. When an input power is large, a high voltage is applied between the gate electrodes 102 and each of the two source/drain electrodes 101. When this voltage exceeds the gate breakdown voltage, the gate Schottky barrier diode breaks down, increasing the loss of the input signals. With the present invention, alleviating the electric field concentration of the angled portions 107 in the gate electrode 102 increases the gate breakdown voltage, allowing transmission of larger input power.

Furthermore, FIG. 3 illustrates ESD breakdown voltage between the gate electrode 102 and the source/drain electrodes 101 of the FET 900 according to the prior art and the FET 100 according to this example by a machine model. As shown in FIG. 3, applying the present invention improves tolerance to breakdown. This is because, as described above, the electric field concentration at the angled portion of the gate electrodes 102 is reduced.

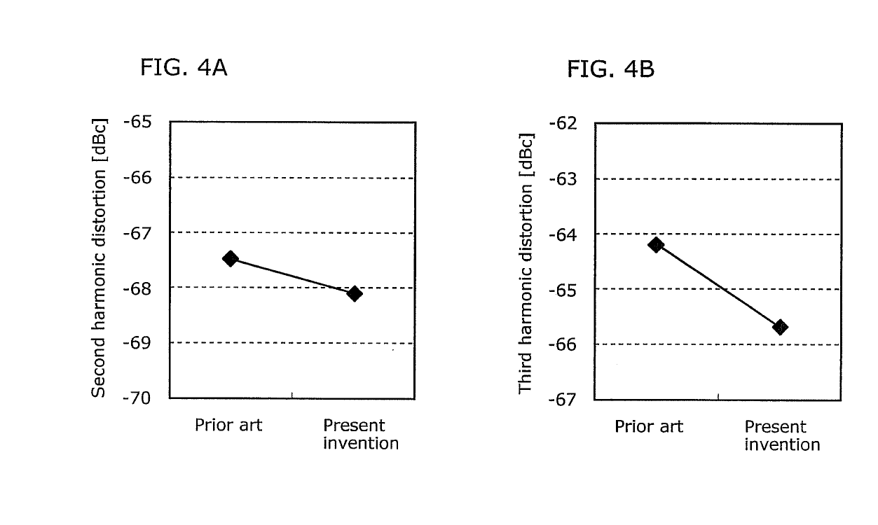

Furthermore, FIG. 4A shows second harmonic distortions of the FET 900 according to prior art and the FET 100 according to this example; and FIG. 4B shows third harmonic distortions of the FET 900 according to prior art and the FET 100 according to this example. The input signal has a power of 26 dBm, and a frequency of 2 GHz. The drawings show that applying the present invention suppresses generation of the harmonic distortion. This is because improvement on evenness of transistor characteristics by increasing the gate breakdown voltage and inactivating the angled portion renders the gate-drain capacitance, the gate-source capacitance, drain-source capacitance, and the drain current less dependent on voltages, thereby improving linearity.

Note that, the switching device according to this example used for measuring P1dBs, ESD breakdown voltages, the second harmonic distortions, and the third harmonic distortions is a 1-stage FET with the gate width of 2 mm.

Note that, although FIG. 1A illustrates an example in which an angle of the gate electrode 102 and the conductive layer 103 at the angled portions 107 is 90 degrees, the present invention is not limited by the shape of the angled portion 107. For example, the present invention is useful even when the gate electrode 102 and the conductive layer 103 form a semi-circle shape at the angled portion 107. Furthermore, in this example, the conductive layer 103 is formed by patterning the contact layer 115. Thus, the region in which the conductive layer 103 is formed is the active region 104. Although it is not particularly limiting, using the semiconductor layer formed in the active region 104 as the conductive layer can reduce cost by simplifying manufacturing process, compared to a case in which a metal film is used. Further miniaturization of devices may be possible as well since the device will not be affected by the processing precision of the metal film.

### Example 2

In this example, differences from Example 1 shall be described in detail. Note that description for the configurations, operations, and effects equivalent to Example 1 shall be omitted.

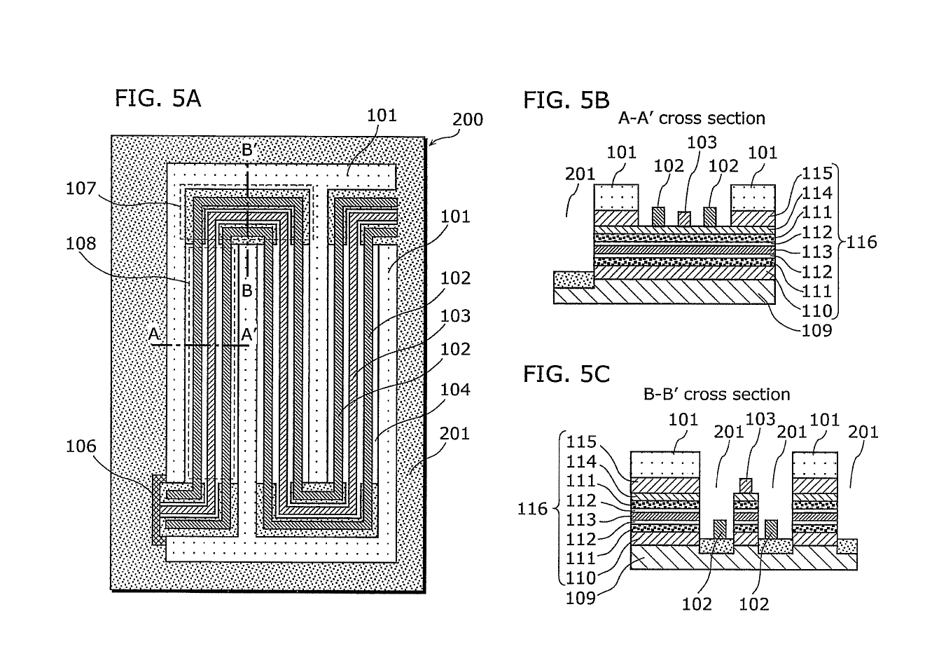

FIG. 5A is a planar view of the FET 200 in this example. FIG. 5B illustrates a cross-sectional view (cross-sectional view along A-A′ in FIG. 5A) of the FET 200, and FIG. 5C illustrates a cross-sectional view of the FET 200 (cross-sectional view along B-B′ in FIG. 5A).

In this example, the inactive region 201 is formed by forming trenches in the epitaxial layer 116 to a depth exposing the buffer layer 110 at the uppermost surface by etching, and performing ion implantation.

The FET 200 in FIG. 5A is a meander-shaped FET in which multiple unit FETs are electrically connected in parallel, and has the same configuration as the FET 100 in FIGS. 1A to 1C in the first embodiment except for the configuration of the inactive region.

The configuration of the inactive region 201 in this example shall be described with reference to a cross-sectional view of the FET 200. As illustrated in FIG. 5B, the FET 200 is formed in the active region 104 in the straight-line portions 108. Note that, the inactive region 201 formed by etching and ion implantation is formed outside of the FET 200 for isolating devices. Accordingly, the FET 200 is formed in the mesa region of the epitaxial layer 116; the periphery of the FET 200 has been etched. In contrast, at the angled portion 107, as illustrated in FIG. 5C, in addition to the device isolation outside of the FET 200, the inactive region 201 is formed from the buffer layer 110 immediately underneath the gate electrode 102 to the semiconductor layer underneath.

There is a known configuration in which the inactive region is formed by etching and ion implantation which allows forming a high-resistance region easily in order to suppress the interference between devices and leaked signals. The inactive region according Embodiments of the present invention can be provided in addition to such a configuration.

Note that, when a high-resistance substrate such as semi-insulating substrate is used, a high-resistance inactive region can be formed by etching only. Thus, it is possible to form the inactive region 105 under the gate electrode 102 in the angled portions 107 without ion implantation and by etching only. Such a case is also included in the present invention.

### Example 3

In this example, differences from Example 1 shall be described in detail. Note that description for the configurations, operations, and effects equivalent to Example 1 shall be omitted.

In this example, the effects of the present invention can be achieved by providing an insulating film 301 immediately underneath the gate electrode 102 of the angled portion 107 instead of the inactive region 105 according to Example 1. The configurations of the semiconductor substrate 109 and the epitaxial layer 16 are identical to those in Example 1.

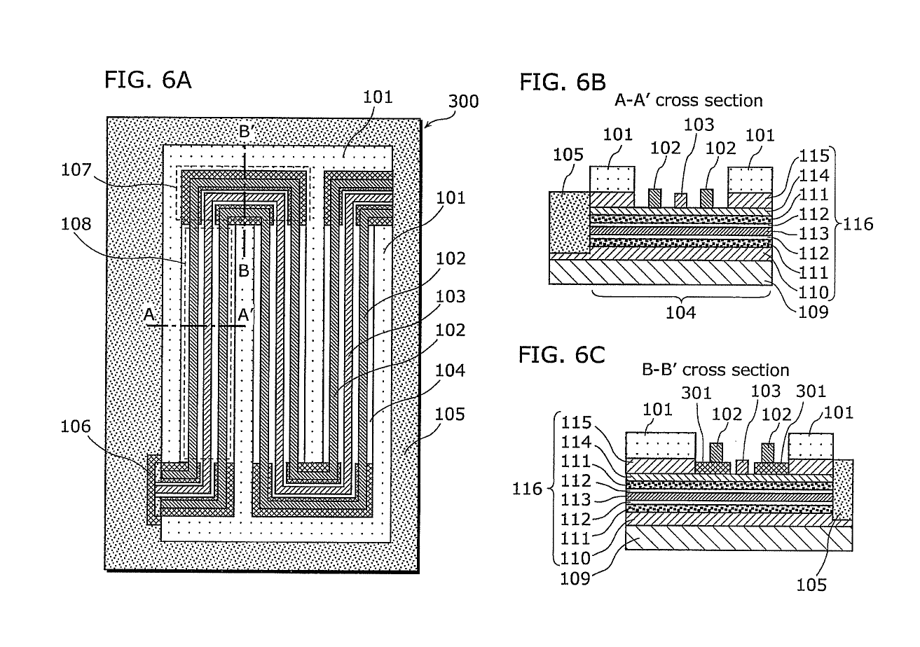

FIG. 6A is a planar view of the FET 300 in this example. FIG. 6B illustrates a cross-sectional view (along the cross-section A-A′ in FIG. 6A) of the FET 300, and FIG. 6C illustrates a cross-sectional view of the FET 300 (along the cross section B-B′ in FIG. 6A).

The FET 300 in FIG. 6A is a meander-shaped FET in which multiple unit FETs are connected in parallel, and has the same configuration as the FET 100 in FIGS. 1A to 1C in Example 1 except that the gate electrode 102 is formed on the insulating film 301 in the angled portion 107. The gate electrode 102 is formed in the active region 104 in the straight-line portions 108 interposed between teeth of the two source/drain electrodes 101, and is formed on the insulating film 301 in the angled portions 107 connecting the adjacent straight-line portions.

The configuration at the straight-line portions 108 and the angled portions 107 shall be described with reference to a cross-sectional view of the FET 300. As illustrated in FIG. 6B, the FET 300 is formed in the active region 104 in the straight-line portions 108. Note that, the inactive region 105 is formed outside the FET 300 for isolating devices. In contrast, as illustrated in FIG. 6C, the gate electrodes 102 are formed on the insulating film 301 in the angled portion 107.

As described above, the gate electrode 102 formed on the active region 104 in the angled portion 107 degrades the power durability due to electric field concentration and degrades the distortion characteristics due to uneven transistor characteristics. However, forming the gate electrode 102 on the insulating film 301 prevents such degradations.

Note that, an example in which the semiconductor layer under the insulating film 301 is the active region 104 is explained in this example. However, the effects of the present inventions can be achieved even if the semiconductor layer is the inactive region 105. Therefore, the present invention includes a case in which the semiconductor layer under the insulating film 301 is modified to the inactive region 105.

### Example 4

In this example, differences from Example 1 shall be described in detail. Note that description for the configurations, operations, and effects equivalent to Example 1 shall be omitted.

In this example, the present invention is applied to MOSFET.

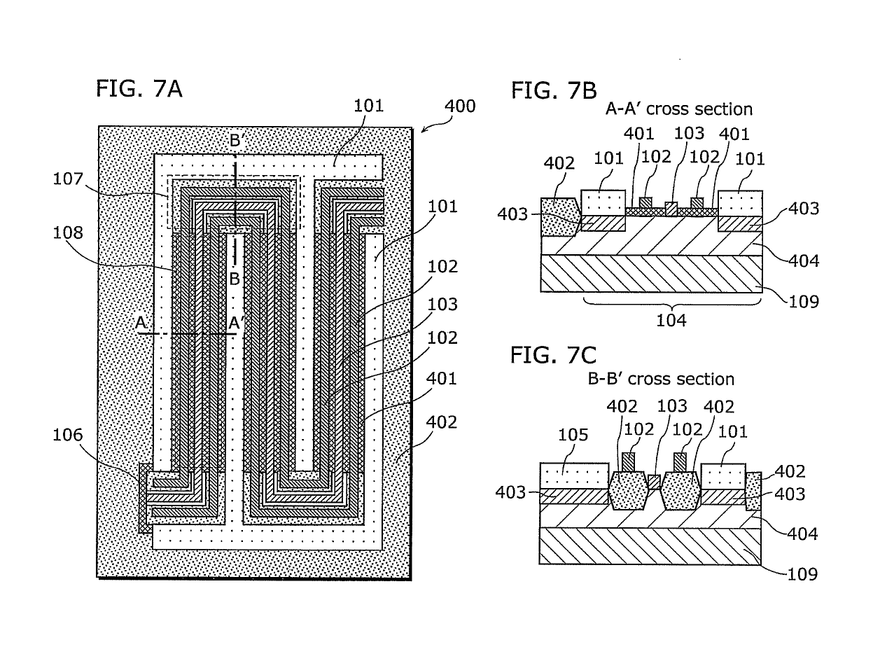

FIG. 7A is a planar view of the FET 400 in this example. FIG. 7B illustrates a cross-sectional view (along the cross-section A-A′ in FIG. 7A) of the FET 400, and FIG. 7C illustrates a cross-sectional view of the FET 400 (along the cross section B-B′ in FIG. 7A).

The FET 400 according to this example includes a semiconductor substrate 109, a p-type doped semiconductor layer 404, source/drain regions 403, source/drain electrodes 101, a gate insulating film 401, gate electrodes 102, a conductive layer 103, and a device isolation region 402. The device isolation region 402 is formed by the LOCal Oxidation of Silicon (LOCOS), for example. Furthermore, semi-insulating substrates such as Silicon on Insulator (SOI) substrates and Silicon on Sapphire (SOS) substrates are particularly suitable for the semiconductor substrate 109.

The FET 400 illustrated in FIG. 7A is a meander-shaped FET in which multiple unit FETs are electrically connected in parallel. The FET 400 is similar to the FET 100 in FIG. 1A in Example 1 in that the gate electrode 102 is formed on the active region 104 in the straight-line portions 108, and the gate electrode 102 is formed on the inactive region 105 in the angled portion 107. However, while the gate electrode 102 is formed on the gate insulating film 401 in the straight-line portions 108, the gate electrode 102 is formed on the insulating film in the device isolation region 402 in the inactive region 105. Here, the insulating film of the device isolation region 402 is substantially thicker than the gate insulating film 401. Thus, the angled portion 107 does not operate as a transistor.

As described above, the gate electrode 102 formed on the active region 104 in the angled portion 107 degrades power durability due to electric field concentration and degrades distortion characteristics due to uneven transistor characteristics. However, with the configuration described above, the present invention is also useful for MOSFET. Note that, although the description above is for N-channel type MOSFET, it is evident that the same effects can be achieved in P-channel type MOSFET.

### Embodiment 2

A radio-frequency signal switch according to Embodiment 2 of the present invention shall be described.

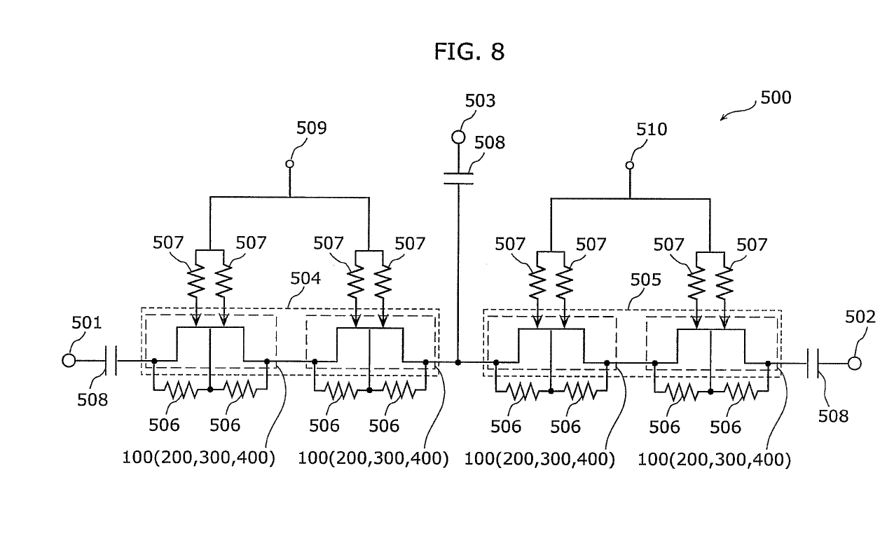

FIG. 8 is a circuit diagram of the radio-frequency signal switch 500 according to this embodiment. The radio-frequency signal switch 500 is a single pole double throw radio-frequency signal switch to which the switching device illustrated in Embodiment 1 is applied, and includes: a receiving terminal 501, the transmission terminal 502, an antenna terminal 503, a first FET unit 504 connected between the receiving terminal 501 and the antenna terminal 503, a second FET unit 505 connected between the transmission terminal 502 and the antenna terminal 503, an electric potential fixed resistor 506, a gate resistor 507, a radio-frequency coupling capacitance 508, a control terminal 509 of the first FET unit 504, and a control terminal 510 of the second FET unit 505.

Each of the FET units 504 and 505 in the radio frequency signal switch 500 has a configuration in which the switching devices illustrated in Embodiment 1 (for example, any of the FETs 100, 200, 300, and 400) are connected in series in two stages.

Using the switching device according to Embodiment 1 of the present invention allows implementation of a radio-frequency signal switch with good distortion characteristics and high power durability. Furthermore, the switching device according to Embodiment 1 of the present invention has the same structure for extending lines as the conventional switching device, which increases compatibility to the conventional circuit layout technology and facilitates application with regard to circuit design.

Note that, in this embodiment, the single pole double throw radio-frequency signal switch having one transmission terminal 502, one receiving terminal 501, and one antenna terminal 503. However, the present invention is not limited to the configuration described above. In addition, the number of stages in the FET units 504 and 505 and method of connecting the electric potential fixed resistor 506 are illustrated as an example. The effects of the present invention can be achieved with modifications where necessary. More specifically, the radio-frequency signal switch using the switching device in Embodiment 1 (for example, any of the FETs 100, 200, 300, and 400) are widely included in the present invention.

### Embodiment 3

A radio-frequency signal amplification module according to Embodiment 3 of the present invention shall be described.

In mobile communication terminals such as mobile phones, output power of an amplifier is controlled depending on the distance from a base station in order to reduce power consumption. More specifically, the output power of the amplifier is controlled to be low when the base station is close, and is controlled to be high when the base station is far.

It is preferable for the amplifier used for such a purpose to be highly efficient regardless of the level of the output power. However, theoretically, the efficiency of the amplifier varies depending on the output power, and thus one amplifier cannot achieve highest efficiency for various output powers. As a solution to this problem, there is a known technology in which amplifiers are switched according to the output power for expanding an output power range with high efficiency.

This embodiment relates to a radio-frequency signal amplification module which uses the switching device according to Embodiment 1 of the present invention is used for switching the amplifiers.

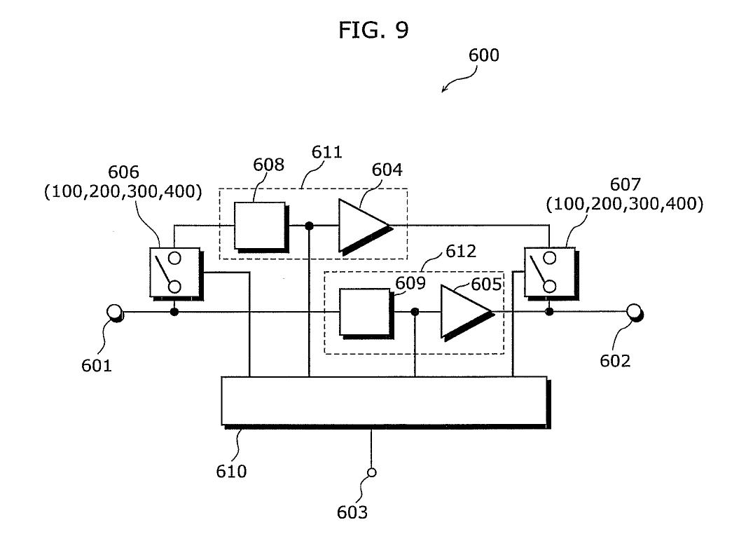

FIG. 9 is a block diagram of radio-frequency signal amplification module 600 according to this embodiment. This embodiment includes an input terminal 601, an output terminal 602, a power supply terminal 603, a first amplifier circuit 611, a second amplifier circuit 612, a first radio-frequency signal switch 606, a second radio-frequency signal switch 607, and a controller 610.

Each of the first radio-frequency signal switch 606 and the second radio-frequency signal switch 607 is configured with the switching device according to Embodiment 1 (for example, any of the FETs 100, 200, 300, and 400).

The first amplifier circuit 611 includes a matching circuit 608 and an amplifier 604. The second amplifier circuit 612 includes a matching circuit 609 and an amplifier 605. The matching circuits 608 and 609 are loaded for matching impedance and for adjusting output powers and efficiency of the amplifiers 604 and 605. In addition, the controller 610 includes a power supply circuit, and, using the power supply voltage applied to the power supply terminal 603, exclusively supplies a bias voltage suitable for operation to the amplifiers 604 and 605, and supplies control signals (for example, gate signals to the FETs 100, 200, 300, and 400) to the radio-frequency signal switches 606 and 607.

The amplifiers 604 and 605 are respectively designed to achieve the maximum efficiency at different output powers. Here, an example in which the amplifier 604 is designed to achieve the maximum efficiency at the time of low output, and the amplifier 605 is designed to achieve the maximum efficiency at the time of high output is used for description.

In this case, the controller 610 supplies bias voltage and control signals such that the amplifier 604 operates, the amplifier 605 is stopped, and the radio-frequency signal switches 606 and 607 conduct at the time of low output. The controller 610 also supplies bias voltage and control signals such that the amplifier 604 is stopped, the amplifier 605 operates, and the radio-frequency signal switches 606 and 607 do not conduct at the time of high output.

As described above, it is necessary to switch signal paths by the radio-frequency signal switch according to the output power. However, the present invention is suitable for, not only the radio-frequency signal switch loaded between the antenna and an internal circuit, but also for a radio-frequency signal switch for switching paths in the internal circuit. Applying the present invention suppresses leaked signal to another path by improving power durability, thereby contributing to an improved efficiency of the amplifier.

Note that, the radio-frequency signal amplification module may be configured by combining an amplifier using a bipolar transistor such as Hetero Bipolar junction Transistor (HBT) and the switching device according to Embodiment 1 of the present invention. The following is an example of the configuration suitable for such a case, including the FET (switching device) according to the present invention and a bipolar transistor (amplifier) formed on one semiconductor substrate.

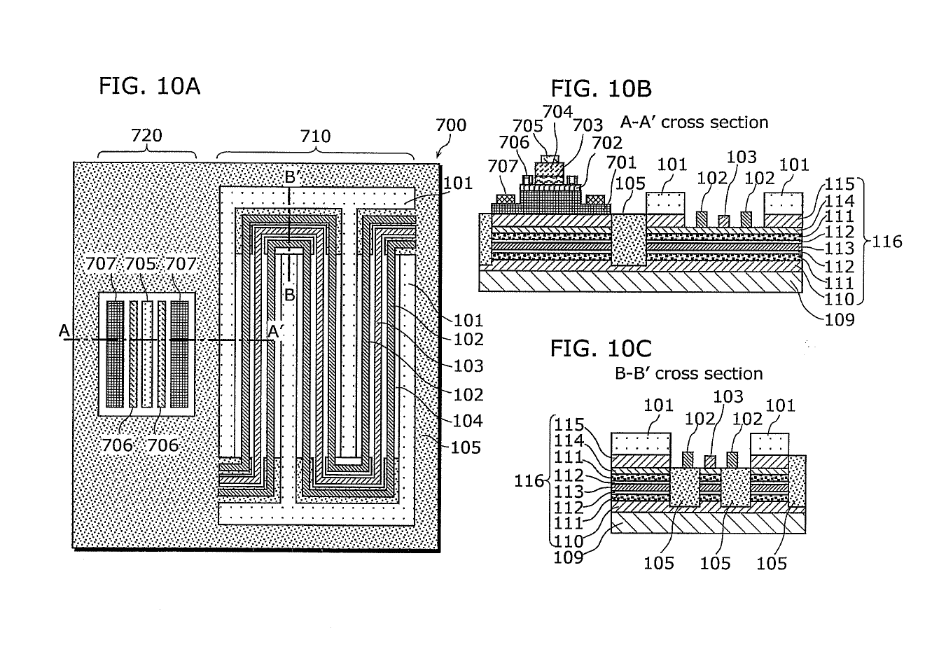

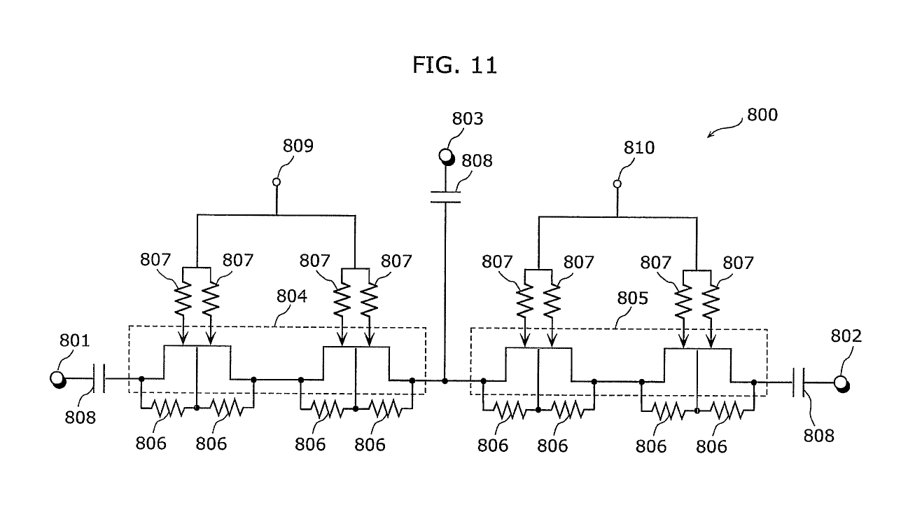

FIG. 10A is a planar view of a semiconductor device 700 which includes the FET 710 and the bipolar transistor 720 formed on one substrate, and FIGS. 10B and 10C illustrate cross-sectional views of the semiconductor device 700 (a cross-sectional view along A-A′ in FIG. 10A and a cross-sectional view along B-B′ in FIG. 10A).

The following description focuses on the difference from the configuration of the FET 100 in Example 1. Note that the description for the rest of the configuration is omitted, since it is the same as Example 1.

On the semiconductor substrate 109, the epitaxial layer 116 is formed to achieve good crystallinity. The epitaxial layer 116 includes the following layers formed on the semiconductor substrate 109 in this order, for example, a buffer layer 110, an electron supply layer 111, a spacer layer 112, a channel layer 113, another spacer layer 112, another electron supply layer 111, a Schottky barrier layer 114, a contact layer 115, a collector layer 701, a base layer 702, an emitter layer 703 and a cap layer 704.

For example, the collector layer 701 is formed of N-type doped GaAs, the base layer 702 is formed of P-type doped GaAs, the emitter layer 703 is formed of N-type doped InGaP, and the cap layer 704 may be formed of N-type doped GaAs. In addition, C (carbon) and others are used as doping species for P-type doping of GaAs.

An emitter electrode 705 is formed on the cap layer. In addition, the base electrode 706 and the collector electrode 707 are formed on the base layer 702 and the collector layer 701 exposed on the surface of the epitaxial layer by etching, respectively. The FET 710 can be formed by the processing procedure described in Example 1 after exposing the contact layer 115 on the surface of the epitaxial layer by etching. Note that, high-resistance inactive region 105 is formed between devices for isolating the devices.

As described above, forming the bipolar transistor 720 configuring the amplifier on the same semiconductor substrate as the FET 710 allows miniaturization of the radio-frequency signal amplification module. In addition, compared to the case where they are formed in different substrates, the embedding process when incorporating the FET and the bipolar transistor into a module is simplified, and thereby reducing manufacturing cost.

Note that, the configuration of the radio-frequency signal amplification module is an application example of the radio-frequency signal switch, and the present invention is not limited by the configurations described above. For example, the number of the stages in amplifiers, the lines and the number of the radio-frequency signal switch and the matching circuit may be changed as necessary. In addition, a radio-frequency signal amplification module including the radio-frequency signal switch switching the antenna and the transmission/reception circuits as illustrated in Embodiment 2 and an amplifier which amplifies transmission signals, and an amplifier which amplifies reception signals can achieve the effects of the present invention.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to a radio-frequency signal switch and a radio-frequency signal amplification module used for radio-frequency front-end module in mobile communication devices.

What is claimed is:

1. A switching device formed on a semiconductor substrate, said switching device comprising:
two source/drain electrodes each of which is comb-shaped and having teeth, said two source/drain electrodes being arranged opposite to each other to interlock the teeth;
at least two gate electrodes which have a meandered shape meandering between said two source/drain electrodes; and
a conductive layer interposed between adjacent gate electrodes among said at least two gate electrodes and along the adjacent gate electrodes,
wherein a layer immediately underneath straight-line portions of said at least two gate electrodes is electrically separated from a layer immediately underneath angled portions of said at least two gate electrodes, each of the straight-line portions being in parallel with each of the teeth of said two source/drain electrodes, and each of the angled portions connecting a pair of adjacent straight-line portions.

2. The switching device according to claim 1,
wherein the layer immediately underneath the angled portions of said at least two gate electrodes is a semiconductor layer, and
the semiconductor layer is inactivated by ion implantation.

3. The switching device according to claim 1,
wherein a mesa which is a stacked body including a channel layer is formed on the semiconductor substrate, and
said two source/drain electrodes, said at least two gate electrodes, and said conductive layer are formed on the mesa.

4. The switching device according to claim 3,
wherein trenches deeper than the channel layer are formed in the mesa, and
the angled portions of said at least two gate electrodes are formed on a layer exposed on the trenches in the stacked body.

5. The switching device according to claim 1,
wherein a layer immediately underneath straight-line portions of said conductive layer is electrically connected to a layer immediately underneath angled portions of said conductive layer, each of the straight-line portions being in parallel with each of the teeth of said two source/drain electrodes, and each of the angled portions connecting a pair of adjacent straight-line portions.

6. The switching device according to claim 1,
wherein said conductive layer is an N-type semiconductor layer.

7. The switching device according to claim 1,
wherein the angled portions of said at least two gate electrodes do not function as a gate electrode of a transistor.

8. A single pole double throw radio-frequency signal switch comprising:
an antenna terminal connected to an antenna;
a transmission terminal to which a signal for the antenna is applied;
a receiving terminal for outputting a signal from the antenna;
a first switching device connected between said transmission terminal and said antenna terminal; and
a second switching device connected between said receiving terminal and said antenna terminal,
wherein, said first and second switching devices are configured to be controlled such that (i) at the time of transmission, said first switching device conducts, and said second switching device does not conduct, and (ii) at the time of reception, said first switching terminal conducts, and said second switching device does not conduct, and
each of said first and second switching devices is the switching device according to claim 1.

9. A radio-frequency signal amplification module comprising:
a first terminal to which a radio-frequency signal is applied;
a second terminal for outputting an amplified radio-frequency signal;
a first radio frequency signal switch which is a single pole single throw switch;
a second radio frequency signal switch which is a single pole single throw switch;
a first amplifier (i) having: an input terminal connected to said first terminal through said first radio frequency signal switch; and an output terminal connected to said second terminal through said second radio frequency switch, and (ii) for amplifying a radio frequency signal applied to the input terminal and outputting the amplified radio-frequency signal to the output terminal;
a second amplifier having: an input terminal connected to said first terminal; and an output terminal connected to said second terminal, and for amplifying a radio frequency signal applied to the input terminal and outputting the amplified radio-frequency signal to the output terminal; and
a controller for exclusively operating said first and second amplifiers, and for controlling said first and second radio frequency switches such that said first and second radio frequency signal switches conduct when said first amplifier is in operation, and that said first and second radio frequency signal switches does not conduct when said second amplifier is in operation,
wherein each of said first and second radio frequency signal switches is the switching device according to claim 1.
